(19) United States
(12) Patent Application Publication
(10) Pub. No.: US 2020/0152410 A1
(43) Pub. Date: May 14, 2020

(54) ION BEAM GENERATING DEVICE INCLUDING LIQUID METAL ION SOURCE AND METHOD OF MANUFACTURING THE SAME

(71) Applicant: KOREA BASIC SCIENCE INSTITUTE, Daejeon (KR)

(72) Inventors: Myoung Choul Choi, Cheongju-si (KR); Boo Ki Min, Ansan-si, (KR); Sang Ju Lee, Gimhae-si (KR); Chang Min Choi, Cheongju-si (KR); Ji Young Baek, Daejeon (KR); Jae yeong Eo, Sejong-si (KR); Il Hee Kim, Seoul (KR)

(21) Appl. No.: 16/663,341

(22) Filed: Oct. 25, 2019

(30) Foreign Application Priority Data
Nov. 13, 2018 (KR) 10-2018-0139234

(51) Int. Cl. H01J 37/08

(52) U.S. Cl. CPC H01J 37/08; H01J 2237/065; H01J 2237/0805

(57) ABSTRACT

An ion beam generating device includes a liquid metal ion source configured to melt metal and emit an ion beam, and an extractor disposed under the liquid metal ion source and configured to extract the ion beam emitted from the liquid metal ion source. The liquid metal ion source includes a storage configured to accommodate the metal, an emitter configured to receive the metal from the storage and emit the ion beam, and a heater configured to heat the emitter or the storage. The heater is configured to directly heat the metal accommodated in the storage to melt the metal into a liquid state, and an amount of the ion beam to be extracted is controlled by a voltage difference that changes based on a distance between the emitter and the extractor.

### CROSS-REFERENCE TO RELATED APPLICATION(S)

This application claims the priority benefit of Korean Patent Application No. 10-2018-0139234 filed on Nov. 13, 2018, in the Korean Intellectual Property Office, the disclosure of which is incorporated herein by reference for all purposes.

### BACKGROUND

### 1. Field

One or more example embodiments relate to an ion beam generating device including a liquid metal ion source, and a method of manufacturing the ion beam generating device.

### 2. Description of Related Art

An integrated ion beam device equipped with a gallium ion source has been developed and used for circuit formation, mask repair, surface analysis, and the like in manufacturing a semiconductor integrated circuit (SIC). For the integrated ion beam device, a liquid metal ion source is used. Such existing liquid metal ion source may concentrate an electric field at a tip of a needle-type electrode and apply an electric field of a threshold value or greater to form a conical protrusion called Taylor cone by liquid metal at the tip of the needle-type electrode and extract ions from the tip.

To manufacture the existing liquid metal ion source, required is a process of providing metal in a crucible and heating it at a high temperature to melt the metal into liquid, and immersing an emitter of the liquid metal ion source in the crucible to fill a storage with liquid metal. In such process, each component of the liquid metal ion source may be deformed by the high heat of the crucible. In addition, when the liquid metal ion source used in such ion beam generating device is depleted, the liquid metal ion source may need to be replaced, and frequent replacements may cause inconvenience.

### SUMMARY

An aspect provides an ion beam generating device including a liquid metal ion source, and a method of manufacturing the ion beam generating device that may remove an operation of immersing an emitter in a crucible by directly heating metal accommodated in a storage to manufacture the liquid metal ion source, and may prevent an end portion of the emitter from being deformed by high heat.

In addition, the ion beam generating device including the liquid metal ion source, and the method of manufacturing the ion beam generating device may remove an additional component such as the crucible used to melt metal, and thus streamline an overall structure of the ion beam generating device.

According to an example embodiment, there is provided an ion beam generating device including a liquid metal ion source configured to melt metal and emit an ion beam, and an extractor disposed under the liquid metal ion source and configured to extract the ion beam emitted from the liquid metal ion source.

The liquid metal ion source may include a storage configured to accommodate the metal, an emitter configured to receive the metal from the storage and emit the ion beam, and a heater configured to heat the emitter or the storage. The heater may directly heat the metal accommodated in the storage to melt the metal into a liquid state. An amount of the ion beam to be extracted may be controlled by a voltage difference that changes based on a distance between the emitter and the extractor.

The emitter and the storage may be formed of tungsten (W), and a diameter of the emitter and the storage may be formed to be between 200 micrometers (μm) and 500 μm. In addition, one end of the emitter may be formed in a shape having a pointed portion. The storage may be formed in a shape of a tube, and extend in a direction from an upper side of the emitter towards a lower side of the emitter while surrounding an area around the emitter.

The distance between the emitter and the extractor may be controlled to be between 400 μm and 1500 μm.

The metal accommodated in the storage may be flushed for 10 seconds under a current condition of 3 amperes (A) to 5 A.

An accelerating voltage to be applied to the emitter may be greater than or equal to 5.0 kilovolts (kV).

The metal accommodated in the storage may be formed of one of or a combination of two or more of gallium (Ga), bismuth (Bi), gold (Au), manganese (Mn), and indium (In).

The metal accommodated in the storage may be formed of an alloy having a melting point of 500° C. or less.

According to another example embodiment, there is provided a method of manufacturing an ion beam generating device, the method including providing metal to a storage configured to transfer the metal to an emitter configured to emit an ion beam, melting the metal accommodated in the storage into a liquid state by directly heating the storage by a heater, and controlling a distance between the emitter and an extractor disposed under the emitter and changing a voltage difference between the emitter and the extractor, and controlling an amount of the ion beam to be extracted.

The providing of the metal to the storage may include providing the metal formed of one of or a combination of two or more of gallium (Ga), bismuth (Bi), gold (Au), manganese (Mn), and indium (In), or providing the metal formed of an alloy having a melting point of 500° C. or less.

The melting of the metal into the liquid state by directly heating the storage may include flushing the metal accommodated in the storage for 10 seconds under a current condition of 3 A to 5 A.

The controlling of the distance between the emitter and the extractor may include controlling the distance between the emitter and the extractor to be between 400 μm and 1500 μm.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the present disclosure will become apparent and more readily appreciated from the following description of example embodiments, taken in conjunction with the accompanying drawings of which:

FIG. 1A is a diagram illustrating an existing liquid metal ion source;

FIG. 1B is a diagram illustrating a liquid metal ion source according to an example embodiment;

FIG. 2 is a diagram illustrating an ion beam generating device including a liquid metal ion source according to an example embodiment; and

FIG. 3 is a flowchart illustrating a method of manufacturing an ion beam generating device according to an example embodiment.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, operations, elements, and/or components, but do not preclude the presence or addition of one or more other features, integers, operations, elements, components, and/or groups thereof.

Terms such as first, second, A, B, (a), (b), and the like may be used herein to describe components. Each of these terminologies is not used to define an essence, order, or sequence of a corresponding component but used merely to distinguish the corresponding component from other component(s). For example, a first component may be referred to as a second component, and similarly the second component may also be referred to as the first component.

It should be noted that if it is described in the specification that one component is “connected,” “coupled,” or “joined” to another component, a third component may be “connected,” “coupled,” and “joined” between the first and second components, although the first component may be directly connected, coupled or joined to the second component. In addition, it should be noted that if it is described in the specification that one component is “directly connected” or “directly joined” to another component, a third component may not be present therebetween. Likewise, expressions, for example, “between” and “immediately between” and “adjacent to” and “immediately adjacent to” may also be construed as described in the foregoing.

Unless otherwise defined, all terms, including technical and scientific terms, used herein have the same meaning as commonly understood by one of ordinary skill in the art to which this disclosure pertains based on an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

Hereinafter, some example embodiments will be described in detail with reference to the accompanying drawings. Regarding the reference numerals assigned to the elements in the drawings, it should be noted that the same elements will be designated by the same reference numerals, wherever possible, even though they are shown in different drawings.

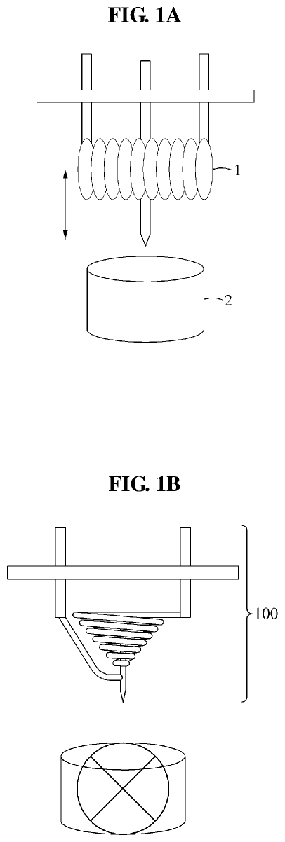

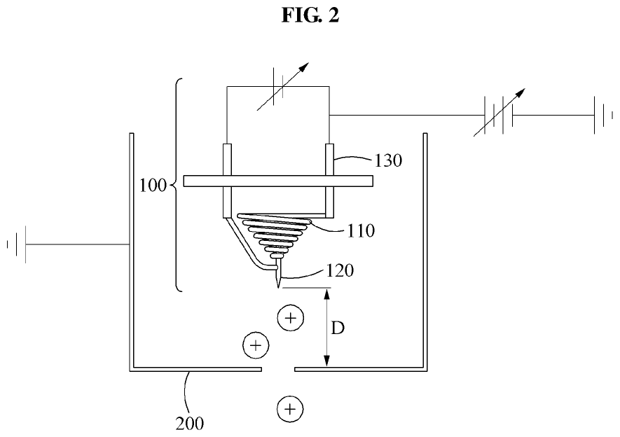

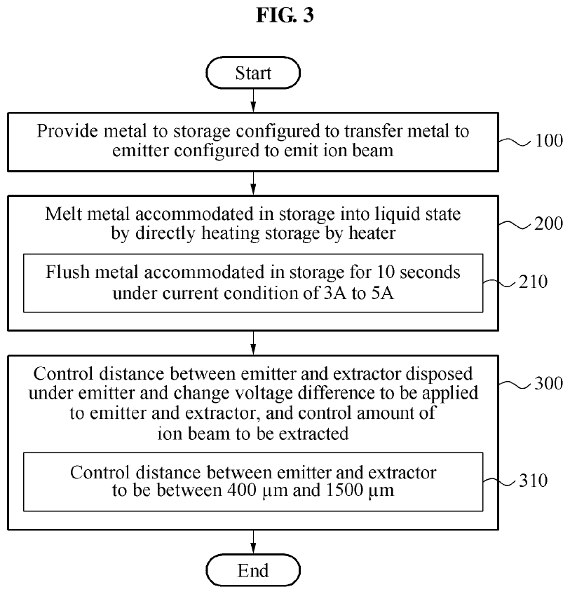

FIG. 1A is a diagram illustrating an existing liquid metal ion source. FIG. 1B is a diagram illustrating a liquid metal ion source according to an example embodiment. FIG. 2 is a diagram illustrating an ion beam generating device including a liquid metal ion source according to an example embodiment. FIG. 3 is a flowchart illustrating a method of manufacturing an ion beam generating device according to an example embodiment.

Referring to FIG. 1A, an existing method of manufacturing a liquid metal ion source 1 includes melting metal in a crucible 2 into a liquid state to store liquid metal in a storage of the liquid metal ion source 1, and immersing an emitter of the liquid metal ion source 1 in the crucible 2 to allow the liquid metal to be accommodated in the storage through the emitter.

Such existing immersing method may require a crucible to store liquid metal in a storage, a first vacuum chamber for the storing to be performed, and a second vacuum chamber to assembly and use a manufactured liquid metal ion source in an ion beam generating device. Thus, the existing immersing method may require the additional vacuum chambers, and the liquid metal ion source may be exposed to an atmospheric condition while the liquid metal ion source is moving between the vacuum chambers.

In addition, the existing immersing method may immerse an emitter of a liquid metal ion source in a high-temperature crucible, and it is thus highly likely that an end portion of an etched emitter may be deformed by the immersing.

Thus, according to an example embodiment, there is provided an ion beam generating device including a liquid metal ion source. Referring to FIG. 1B, the ion beam generating device does not include a crucible to melt metal into a liquid state, and directly melts metal accommodated in a storage using a heater.

Through such structure, it is possible to remove an additional component such as a crucible, and thus simplify and streamline an overall configuration of the ion beam generating device. In addition, it is possible to manufacture a liquid metal ion source in a single chamber, and emit an ion beam. Thus, there is no probability that the liquid metal ion source is exposed to air, and thus metal may not be exposed to air and thereby not being oxidized. In addition, an emitter of the liquid metal ion source may not need to be immersed in a high-temperature crucible, and thus an end portion of the emitter may not be deformed.

In detail, referring to FIG. 2, an ion beam generating device according to an example embodiment includes a liquid metal ion source 100 configured to melt metal and emit an ion beam, and an extractor 200 disposed under the liquid metal ion source 100 and configured to extract the ion beam emitted from the liquid metal ion source 100.

The liquid metal ion source 100 includes a storage 110 configured to accommodate the metal, an emitter 120 configured receive the metal from the storage 110 and emit the ion beam, and a heater 130 configured to heat the emitter 120 or the storage 110. The heater 130 is configured to directly heat the metal accommodated in the storage 110 to melt the metal into a liquid state, and an amount of the ion beam to be extracted is controlled by a voltage difference that changes based on a distance between the emitter 120 and the extractor 200.

The emitter 120 and the storage 110 are formed of tungsten (W), and a diameter of the emitter 120 and the storage 110 is formed between 200 micrometers (μm) and 500 μm. In addition, one end of the emitter 120 is formed in a shape having a pointed portion, and the storage 110 is formed in a shape of a tube. The storage 110 extends in a direction from an upper side of the emitter 120 towards a lower side of the emitter 120 while surrounding an area around the emitter 120. Thus, an overall shape of the storage 110 may be a funneled shape. That is, a width of the overall shape of the storage 110 gradually decreases towards the lower side from the upper side.

The metal accommodated in the storage 110 of the ion beam generating device is flushed for 10 seconds under a current condition of 3 amperes (A) to 5 A. Under such condition, it is possible to melt the metal accommodated in the storage 110 into a liquid state without applying a stress to the storage 110.

In addition, an accelerating voltage to be applied to the emitter 120 of the ion beam generating device is 5.0 kilovolts (kV) or greater, and a distance D between the emitter 120 and the extractor 200 of the ion beam generating device is controlled to be between 400 μm and 1500 μm.

In addition, the metal to be accommodated in the storage 110 is formed of one of or a combination of two or more of gallium (Ga), bismuth (Bi), gold (Au), manganese (Mn), and indium (In). Alternatively, the metal to be accommodated in the storage 110 is formed of an alloy having a melting point of 500° C. or less. However, examples are not limited to what has been described in the foregoing, and other types of metal that are desirable for manufacturing the liquid metal ion source 100 may also be used.

Referring to FIG. 3, a method of manufacturing an ion beam generating device includes operation 100 of proving metal to a storage configured to transfer the metal to an emitter configured to emit an ion beam, operation 200 of directly heating the storage by a heater and melting the metal accommodated in the storage into a liquid state, and operation 300 of controlling a distance between the emitter and an extractor disposed under the emitter to change a voltage difference between the emitter and the extractor and control an amount of the ion beam to be extracted.

Operation 100 of providing the metal to the storage includes proving metal formed of one of or a combination of two or more of gallium (Ga), bismuth (Bi), gold (Au), manganese (Mn), and indium (In), or providing metal formed of an alloy having a melting point of 500° C. or less.

Operation 200 of directly heating the storage and melting the metal into a liquid state includes operation 210 of flushing the metal accommodated in the storage for 10 seconds under a current condition of 3 A to 5 A.

Operation 300 of controlling the distance between the emitter and the extractor includes Operation 310 of controlling the distance between the emitter and the extractor to be between 400 μm and 1500 μm.

As described above, an ion beam generating device including a liquid metal ion source, and a method of manufacturing the ion beam generating device may be used to simplify and streamline an overall structure of the ion beam generating device by directly heating metal accommodated in a storage, thereby removing an operation of immersing an emitter in a crucible and preventing an end portion of the emitter from being deformed by high heat.

In addition, the ion beam generating device including the liquid metal ion source, and the method of manufacturing the ion beam generating device may be used to manufacture the liquid metal ion source in a single chamber and emit an ion beam. Thus, it is possible to prevent the liquid metal ion source from being exposed to air and thereby being oxidized.

According to example embodiments described herein, there is provided an ion beam generating device including a liquid metal ion source, and a method of manufacturing the ion beam generating device. By directly heating metal accommodated in a storage, it is possible to remove an operation of immersing an emitter in a crucible from an entire process of manufacturing the liquid metal ion source and prevent an end portion of the emitter from being deformed by high heat.

In addition, it is possible to remove an additional component such as the crucible used to melt metal, and thus simplify and streamline an overall structure of the ion beam generating device and the method of manufacturing the ion beam generating device.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An ion beam generating device, comprising:
a liquid metal ion source configured to melt metal and emit an ion beam; and
an extractor disposed under the liquid metal ion source and configured to extract the ion beam emitted from the liquid metal ion source,
wherein the liquid metal ion source comprises:
a storage configured to accommodate the metal;
an emitter configured to receive the metal from the storage and emit the ion beam; and
a heater configured to heat the emitter or the storage,
wherein the heater is configured to directly heat the metal accommodated in the storage to melt the metal into a liquid state, and
an amount of the ion beam to be extracted is controlled by a voltage difference that changes based on a distance between the emitter and the extractor.

2. The ion beam generating device of claim 1, wherein the emitter and the storage are formed of tungsten (W),
a diameter of the emitter and the storage is formed to be between 200 micrometers (μm) and 500 μm,
one end of the emitter is formed in a shape having a pointed portion, and
the storage is formed in a shape of a tube, and extends in a direction from an upper side of the emitter towards a lower side of the emitter while surrounding an area around the emitter.

3. The ion beam generating device of claim 2, wherein the distance between the emitter and the extractor is controlled to be between 400 μm and 1500 μm.

4. The ion beam generating device of claim 3, wherein the metal accommodated in the storage is flushed for 10 seconds under a current condition of 3 amperes (A) to 5 A.

5. The ion beam generating device of claim 4, wherein an accelerating voltage to be applied to the emitter is greater than or equal to 5.0 kilovolts (kV).

6. The ion beam generating device of claim 5, wherein the metal accommodated in the storage is formed of one of or a combination of two or more of gallium (Ga), bismuth (Bi), gold (Au), manganese (Mn), and indium (In).

7. The ion beam generating device of claim 5, wherein the metal accommodated in the storage is formed of an alloy having a melting point of 500° C. or less.

8. A method of manufacturing an ion beam generating device, comprising:
providing metal to a storage configured to transfer the metal to an emitter configured to emit an ion beam;
melting the metal accommodated in the storage into a liquid state by directly heating the storage by a heater; and
controlling a distance between the emitter and an extractor disposed under the emitter and changing a voltage difference between the emitter and the extractor, and controlling an amount of the ion beam to be extracted.

9. The method of claim 8, wherein the providing of the metal to the storage comprises:
providing the metal formed of one of or a combination of two or more of gallium (Ga), bismuth (Bi), gold (Au), manganese (Mn), and indium (In), or
providing the metal formed of an alloy having a melting point of 500° C. or less, and
the melting of the metal into the liquid state by directly heating the storage comprises:
flushing the metal accommodated in the storage for 10 seconds under a current condition of 3 amperes (A) to 5 A.

10. The method of claim 9, wherein the controlling of the distance between the emitter and the extractor comprises:
controlling the distance between the emitter and the extractor to be between 400 micrometers (μm) and 1500 μm.
